(19) United States
(12) Patent Application Publication
(10) Pub. No.: US 2017/0125621 A1
(43) Pub. Date: May 4, 2017

(54) MULTI-JUNCTION SOLAR CELL WITH SELF COMPENSATING SUB-CELLS

(71) Applicant: The Boeing Company, Chicago, IL (US)

(72) Inventors: Douglas R. Jungwirth, Porter Ranch, CA (US); Scott B. Singer, Sherman Oaks, CA (US)

(21) Appl. No.: 14/926,599

(22) Filed: Oct. 29, 2015

(51) Int. Cl. H01L 31/05; H01L 31/0687

(52) U.S. Cl. CPC H01L 31/0504; H01L 31/0687

(57) ABSTRACT

A semiconductor device is disclosed, and includes a first sub-cell generating a first electrical current, a second sub-cell generating a second electrical current, and at least one power converter. The first sub-cell and the second sub-cell are electrically coupled to one another in series. The power converter is electrically coupled to both the first sub-cell and the second sub-cell. The power converter introduces a compensating current into at least one of the first sub-cell and the second sub-cell to balance the first electrical current and the second electrical current to be substantially equal to one another.

### FIELD

The disclosed system and method relate to a semiconductor device and, more particularly, to a semiconductor device including a first sub-cell, a second sub-cell and at least one power converter that introduces a compensating current into at least one of the first sub-cell and the second sub-cell to balance electrical current.

### BACKGROUND

Multi junction solar cells include at least two sub-cells electrically stacked on top of one another. Each individual sub-cell may be a combination of a layer of p-doped semiconductor material grown on top of n-doped semiconductor material to create a p-n junction. Alternatively, n-doped semiconductor material may be grown on top of p-doped semiconductor material to create a n-p junction. The semiconductor materials and the doping concentration of each sub-cell may be selected to absorb a specific optical wavelength of incident light. Accordingly, each p-n junction produces electric current based on the different optical wavelengths of incident light. Useable electric current may be collected from the solar cell by placing an electrically conducting set of grid lines along an upper surface and a lower surface of the multi junction solar cell. It is to be appreciated that a typical multi junction solar cell is structured such that the grid lines may be accommodated along only the upper and lower surfaces of the solar cell.

A multi junction solar cell may be limited in the amount of electric current produced. Specifically, the electric current may be limited by the sub-cell that produces the least amount of electric current. For example, if one of the sub-cells of a multi junction solar cell only produces about one Ampere of current, while the remaining sub-cells each produce about five Amperes of current, then the multi junction solar cell is capable of producing only one Ampere of current. The excess current generated by the other sub-cells is dissipated into heat, and is not used for electrical power production.

Multiple multi junction solar cells are typically electrically interconnected to form a circuit that produces higher voltages than are possible with a single solar cell. A typical solar panel is formed by electrically connecting several circuits, in parallel and/or in series, in order to produce higher currents or higher voltages. Specifically, multiple individual solar cells may be electrically connected together in series to generate a peak voltage. This configuration of individual solar cells connected together in series is sometimes referred to as a string. Strings of individual solar cells may then be electrically connected to one another in parallel to maintain the peak voltage and to increase the electrical current that may be generated. However, it is to be appreciated that the electrical current produced by a single string is limited to the individual solar cell that produces the least amount of electric current. Thus, if a shadow is cast along one or more of the individual solar cells in a particular string such that individual solar cells are unable to produce any electrical current at all, then no electrical current may be produced by that particular string. Furthermore, if one or more of the individual solar cells of a particular string are somehow blocked such that the solar cell is only able to produce a portion of the total current possible, then that particular string is limited to producing the total amount of electrical current by the blocked solar cell. Thus, there exists a continuing need in the art to improve the electrical efficiency of solar panels and multi junction solar cells.

### SUMMARY

In one example, a semiconductor device is disclosed, and includes a first sub-cell generating a first electrical current, a second sub-cell generating a second electrical current, and at least one power converter. The first sub-cell and the second sub-cell are electrically coupled to one another in series. The power converter is electrically coupled to both the first sub-cell and the second sub-cell. The power converter introduces a compensating current into at least one of the first sub-cell and the second sub-cell to balance the first electrical current and the second electrical current to be substantially equal to one another.

In another example, a solar panel is disclosed, and includes at least one solar cell string having a plurality of solar cells electrically coupled to one another in series. Each solar cell generates a respective electrical current. The solar panel also includes a load having a control module. The load is electrically coupled to the at least one solar cell string. The control module determines a compensating current for each individual solar cell of the plurality of solar cells. The compensating current balances the respective electrical current generated by each of the plurality of solar cells within the at least one solar cell string in substantially equal amounts.

In yet another example, a method of balancing current within a multi junction solar cell is disclosed. The method includes generating a first electrical current by a first sub-cell. The method also includes generating a second electrical current by a second sub-cell. The first sub-cell and the second sub-cell are electrically coupled to one another in series. The method further includes electrically coupling both the first sub-cell and the second sub-cell to at least one power converter. Finally, the method includes introducing a compensating current by the at least one power converter into at least one of the first sub-cell and the second sub-cell to balance the first electrical current and the second electrical current to be substantially equal to one another.

Other objects and advantages of the disclosed method and system will be apparent from the following description, the accompanying drawings and the appended claims.

### BRIEF DESCRIPTION OF THE DRAWINGS

FIG. 1 is an exemplary illustration of the disclosed semiconductor device, where the semiconductor device is a solar cell including three sub-cells;

FIG. 2 is a schematic electrical diagram of the solar cell assembly shown in FIG. 1, where the solar cell assembly is electrically coupled to a load;

FIG. 3 is a schematic electrical diagram of a solar panel including a plurality of solar cells as disclosed in FIGS. 1-2;

FIG. 4 is an alternative example of the disclosed semiconductor device shown in FIG. 1; and

FIG. 5 is yet another example of the disclosed semiconductor device shown in FIG. 1.

### DETAILED DESCRIPTION

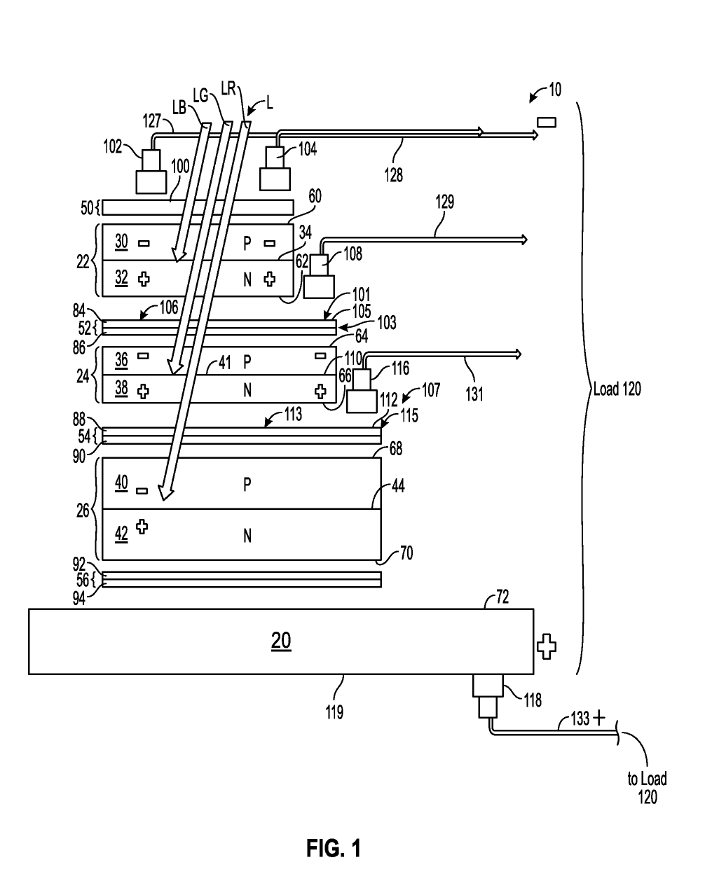

FIG. 1 is an exemplary illustration of the disclosed semiconductor device 10. In the example as shown, the semiconductor device 10 is a multi-junction solar cell including a substrate 20 and two or more sub-cells, which may also be referred to as photovoltaic cells. Specifically, in the example as shown in FIG. 1, the semiconductor device 10 is a 3-junction photovoltaic cell including a first sub-cell 22, a second sub-cell 24, and a third sub-cell 26. The sub-cells 22, 24, 26 may also be referred to by the order in which incident light L strikes each sub-cell as the incident light enters the semiconductor device 10. For instance in FIG. 1, the first sub-cell 22 may also be referred to as a top sub-cell, the second sub-cell 24 may be referred to as the middle sub-cell, and the third sub-cell 26 may be referred to as the bottom sub-cell.

It is to be appreciated that while a 3-junction photovoltaic cell is described and illustrated in FIG. 1, the disclosure is not limited to the present illustration. Instead, the semiconductor device 10 may include two or more sub-cells. Furthermore, although FIG. 1 illustrates a solar cell, it is to be appreciated that the semiconductor device 10 should not be limited to a solar Indeed, the semiconductor device 10 may be used in a variety of optoelectronic devices such as, for example, laser power converters.

Each of the sub-cells 22, 24, 26 may include at least one layer of p-doped and at least one layer of n-doped semiconductor material. Specifically, in the example as illustrated the first sub-cell 22 includes a p-doped layer 30 and a n-doped layer 32. The layers 30, 32 define a p-n junction 34 therebetween. The second sub-cell 24 includes a p-doped layer 36 and a n-doped layer 38. The layers 36, 38 define a p-n junction 41 therebetween. The third sub-cell 26 includes a p-doped layer 40 and a n-doped layer 42. The layers 40, 42 define a p-n junction 44 therebetween. In the example as seen in FIG. 1, the p-n junction 34 absorbs a blue wavelength L_{B} of incident light L, the p-n junction 41 absorbs a green wavelength L_{G} of incident light L, and the p-n junction 44 absorbs a red wavelength L_{R} of incident light L. It is to be appreciated that while each sub-cell 22, 24, 26 is illustrated as including a p-doped layer grown on top of a n-doped layer, in an alternative example the sub-cells 22, 24, 26 may include a n-doped layer grown on top of a p-doped layer.

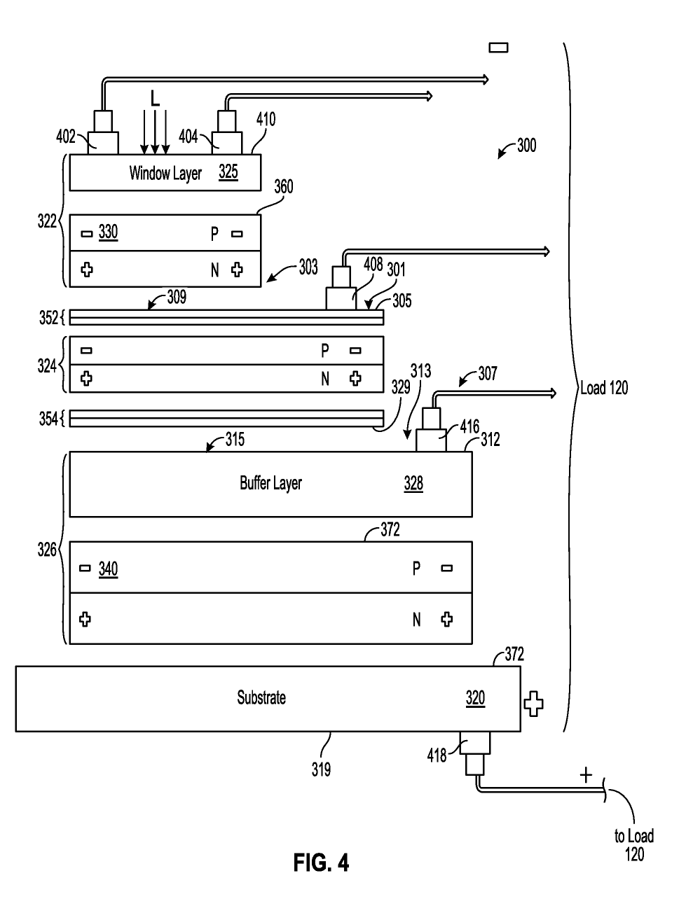

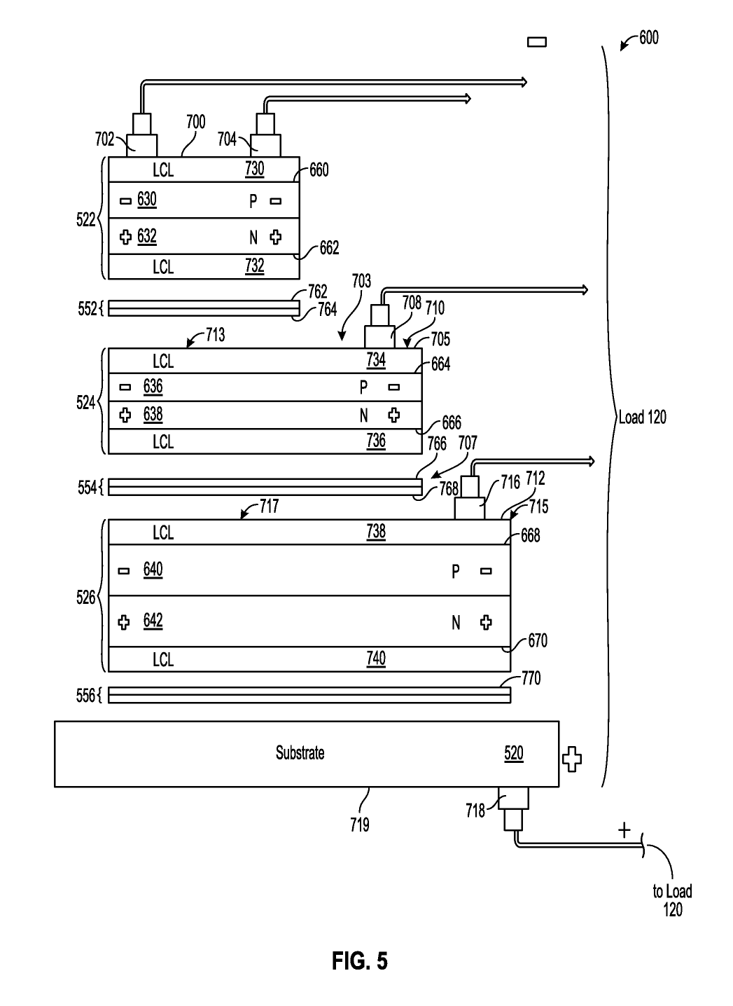

The layers 30, 32, 36, 38, 40, and 42 may be constructed of Group III-V materials. The substrate 20 serves as a substrate for epitaxial growth of the layers that form the sub-cells 22, 24, 26, and may be constructed of materials such as, for example, germanium (Ge), silicon (Si), or mercury telluride (HgTe). The substrate 20 may also serve as the main mechanical support for the semiconductor device 10. Although FIG. 1 illustrates the semiconductor device 10 including the substrate 20, it is to be appreciated that the substrate may be omitted in another approach. It is to be understood that while the sub-cells 22, 24, 26 are illustrated including respective p-doped and n-doped layers, one or more of the sub-cells 22, 24, 26 may also include additional semiconductor layers as well such as, for example, a buffer layer 328 (shown in FIG. 4), window layer 325 (shown in FIG. 4), or multiple lateral conduction layers (LCLs) (shown in FIG. 5), which are described in greater detail below.

A contact layer 50 may be disposed along an upper surface 60 of the first sub-cell 22. The contact layer 50 may be constructed of a semiconductor material, such as a p-doped semiconductor material. A tunnel junction 52 may be located between a bottom surface 62 of the first sub-cell 22 and an upper surface 64 of the second sub-cell 24. The tunnel junction 52 couples the first sub-cell 22 and the second sub-cell 24 in electrical series. A tunnel junction 54 may be located between a bottom surface 66 of the second sub-cell 24 and a top surface 68 of the third sub-cell 26. The tunnel junction 54 couples the second sub-cell 24 and the third sub-cell 26 in electrical series. A tunnel junction 56 may be located between a bottom surface 70 of the third sub-cell 26 and an upper surface 72 of the substrate 20. The tunnel junction 56 couples the third sub-cell 26 and the substrate 20 in electrical series. As seen in FIG. 1, each tunnel junction 52, 54, 56 includes a respective n-doped tunnel layer and a respective p-doped tunnel layer. Specifically, the tunnel junction 52 includes a n-doped tunnel layer 84 and a p-doped layer 86, the tunnel junction 54 includes a n-doped tunnel layer 88 and a p-doped layer 90, and the tunnel junction 56 includes a n-doped tunnel layer 92 and a p-doped layer 94. However, the arrangement of the n-doped tunnel layers and the p-doped tunnel layers of the tunnel junctions 52, 54, 56 may be switched (i.e., a p-doped layer grown in top of a n-doped layer) if one or more of the sub-cells 22, 24, 26 include a n-doped layer grown on top of a p-doped layer.

Continuing to refer to FIG. 1, two electrical contacts 102, 104 may be placed along an upper surface 100 of the contact layer 50. The electrical contacts 102, 104 are electrically coupled to the first sub-cell 22. The second sub-cell 24 is stacked below the first sub-cell 22. However, a portion of the first sub-cell 22 and the contact layer 50 have both been removed using any known technique, which results in a first step 103. Thus, a portion of an upper surface 105 of the tunnel junction 52 is covered by the first sub-cell 22, and a remaining portion 101 of the upper surface 105 of the tunnel junction 52 is exposed. An electrical contact 108 may be placed along the exposed portion 101 of the upper surface 105 of the tunnel junction 52. The electrical contact 108 is electrically coupled to the second sub-cell 24. As explained in greater detail below, the step 103 may define a stepped mesa structure of the semiconductor 10. A stepped mesa structure may provide advantages when placing electrical contacts along a surface of the semiconductor device 10.

The third sub-cell 26 is stacked below the second sub-cell 24, where a portion of the second sub-cell 24 and the tunnel junction 52 have both been removed using any known technique, which results in a second step 107. Thus, a portion 113 of an upper surface 112 of the tunnel junction 54 is covered by the second sub-cell 24, and a remaining portion 115 of the upper surface 112 is exposed. An electrical contact 116 may be placed along the exposed portion 115 of the upper surface 112 of the tunnel junction 54. The electrical contact 116 is electrically coupled to the third sub-cell 26. Thus, as seen in FIG. 1, the exposed upper surface 105 of the tunnel junction 52 provides a surface for the electrical contact 108 to be placed along, and the upper surface 112 of the tunnel junction 54 provides a surface for the electrical contact 116 to be placed along. Finally, an electrical contact 118 may be placed along a bottom surface 119 of the substrate 20. The electrical contact 118 is electrically coupled to the substrate 20.

Although FIG. 1 illustrates the electrical contacts 102, 104, 108, 112, 118 disposed along an upper or lower surface of a respective semiconductor layer, it is to be appreciated that this illustration is not intended to be limiting, and the electrical contacts may be placed in other locations as well. Furthermore, although FIG. 1 includes the stepped mesa structure (i.e., the semiconductor device 10 includes steps 103, 107), it should be understood that a stepped mesa structure is not required for placement of the electrical contacts. For example, the semiconductor device 10 may not include steps, and instead the electrical contacts may be disposed along a side surface of a respective semiconductor layer. However, those of ordinary skill in the art will readily appreciate that it may be easier to assemble a semiconductor device having electrical contacts disposed along the upper surface instead of a side surface of a respective semiconductor layer. Alternatively, in another approach that does not require the semiconductor device to include a stepped mesa structure, vias that originate from either the top or the bottom side of the respective semiconductor layer may be used as electrical contacts.

It is to be appreciated that while FIG. 1 shows the electrical contacts 102, 104, 108, 116 placed along the respective upper surfaces of the contact layer 50 and the tunnel junctions 52, 54, this illustration is merely exemplary in nature. The placement of the electrical contacts 102, 104, 108, 116 are not limited to the respective upper surfaces of the contact layer 50 and the tunnel junctions 52, 54. Instead, it is to be appreciated that one or more of the electrical contacts 102, 104, 108, 116 may be electrically coupled to the p-doped layer of one of the sub-cells 22, 24, 26, and another electrical contact may be electrically coupled to the n-doped layer of an adjacent sub-cell 22, 24, 26. For example, in an alternative approach the contact layer 50 may be omitted, thereby exposing the upper surface 60 of the first sub-cell 22. The electrical contacts 102, 104 may be placed along the exposed upper surface 60 of the first sub-cell 22, and are thereby electrically coupled to the p-doped layer 30. Furthermore, a portion of the tunnel junction 52 and the p-doped layer 36 of the second sub-cell 24 may also be removed to define the first step 103. Removing a portion of the tunnel junction 52 and the p-doped layer 36 of the second sub-cell 24 thereby exposes an upper surface 110 of the n-doped layer 38. The electrical contacts 108 may be placed along the exposed upper surface 110 of the n-doped layer 38 of the second sub-cell 24, and are thereby electrically coupled to the n-doped layer 38. Moreover, as seen in FIGS. 4 and 5 and as described in greater detail below, the electrical contacts 102, 104, 108, 116 may also be placed along other semiconductor layers as well.

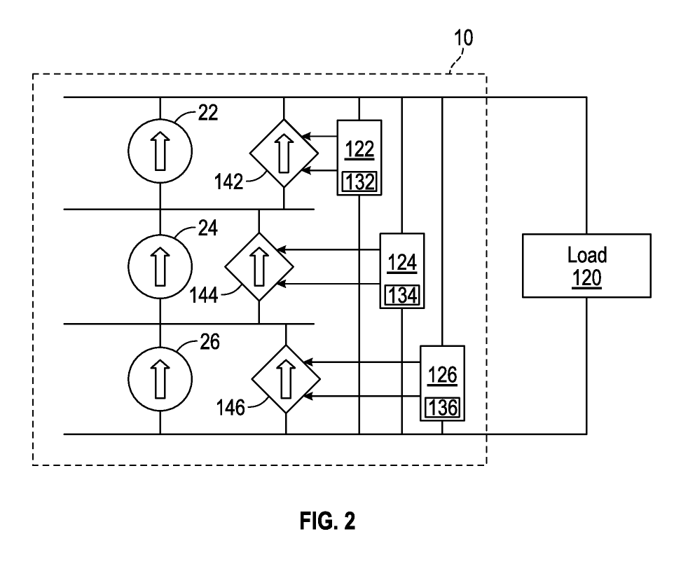

FIG. 2 is a schematic diagram electrically depicting the sub-cells 22, 24, 26 of the semiconductor device 10, which are electrically coupled to a load 120. The load 120 may be a direct current (DC) load. The sub-cells 22, 24, 26 of the semiconductor device 10 are schematically depicted as constant current sources that are electrically coupled to one another in series.

In the example as shown in FIG. 2, a DC to DC power converter is provided for each sub-cell 22, 24, 26 of the semiconductor device 10. A first DC to DC power convertor 122 is electrically coupled to the first sub-cell 22, a second DC to DC power convertor 124 is electrically coupled to the second sub-cell 24, and a third DC to DC power convertor 126 is electrically coupled to the third sub-cell 26. Specifically, referring to both FIGS. 1 and 2, the electrical contacts 102, 104 may electrically couple the first sub-cell 22 with the DC to DC power converter 122 and the load 120 by respective wires 127, 128. The electrical contact 108 may electrically couple the second sub-cell 24 with the DC to DC power converter 124 and the load 120 by wire 129. The electrical contact 116 may electrically couple the third sub-cell 26 with the DC to DC power converter 126 and the load 120 by wire 131. Finally, the electrical contact 118 may electrically couple the substrate 20 to the load 120 by wire 133.

The DC to DC power converters 122, 124, 126 may be micro-devices constructed of a semiconductor material. The DC to DC power converters 122, 124, 126 may be epitaxially grown upon and/or integrated upon the substrate 20 of the semiconductor device 10 (FIG. 1). Furthermore, the DC to DC power converters 122, 124, 126 may be DC to DC buck power converters (also referred to as step-down converters), which step down voltage and step up current. As explained in greater detail below, each DC to DC power converter 122, 124, 126 may introduce a compensating current back into the respective sub-cell 22, 24, 26 in order to balance the electrical current generated by each of the sub-cells 22, 24, 26 such that the sub-cells 22, 24, 26 generate substantially equal current. Those of ordinary skill in the art may appreciate that a substantially equal current between sub-cells 22, 24, 26 result in various technical effects and benefits, which are described in greater detail below.

Each DC to DC power converter 122, 124, 126 may include a respective control module 132, 134, 136. The respective control modules 132, 134, 136 may refer to, or be part of an electronic circuit, a combinational logic circuit, a field programmable gate array (FPGA), a processor (shared, dedicated, or group) that executes code, or a combination of some or all of the above, such as in a system-on-chip. In the example as shown in FIG. 2, the DC to DC power converters 122, 124, 126 are integrated within the semiconductor 10. However, it is to be appreciated that in an alternative example, separate control circuitry external to the semiconductor device 10 may be used to monitor multiple solar cells that are part of a solar array. The external control circuitry may send compensating current to each sub-cell 22, 24, 26 of the semiconductor device 10 (FIG. 1). As explained in greater detail below, the compensating current is used to balance current such that the current generated by each of the sub-cells 22, 24, 26 is substantially equal.

The control modules 132, 134, 136 may each include circuitry or control logic for instructing the respective DC to DC power converter 122, 124, 126 to introduce the compensating current to a respective sub-cell 22, 24, 26. Specifically, each DC to DC power converter 122, 124, 126 produces a respective compensating current 142, 144, 146. The compensating current 142, 144, 146 may be introduced back into the respective sub-cells 22, 24, 26 in order to balance the electrical current generated by each of the sub-cells 22, 24, 26. Specifically, the compensating current 142, 144, 146 may be introduced back into the respective sub-cell 22, 24, 26 such the respective electrical currents generated by each sub-cell 22, 24, 26 are substantially equal to one another.

In one example the first sub-cell 22 may generate about 1.25 Volts and a photon-induced current of about 1.5 Amperes, the second sub-cell 24 may generate about 1.25 Volts and a photon-induced current of about 0.75 Amperes, and the third sub-cell may generate about 0.85 Volts and a photon-induced current of about 2.5 Amperes. Those of ordinary skill in the art will readily appreciate that in a conventional solar cell assembly, which does not include current compensation for each sub-cell, the total power generated by the solar cell assembly would be limited by the least amount of current generated by one of the sub-cells (e.g., about 0.75 Amperes). Thus, in the present example, the power output of a conventional solar cell would only be about 2.5875 Watts.

Unlike conventional solar cell assemblies, the disclosed DC to DC power converters 122, 124, 126 may each produce a respective compensating current 142, 144, 146 that is introduced back into a respective sub-cell 22, 24, 26. Specifically, in the present example, the DC to DC power converter 122 generates a compensating current 142 of about 1 Ampere at 1.25 Volts, the DC to DC power converter 124 generates a compensating current 144 of about 1.75 Amperes at 1.35 Volts, and the DC to DC power converter 126 does not produce any compensating current. Thus, in the present example, the current generated by each of the sub-cells 22, 24, 26 is substantially equal. In other words, each sub-cell 22, 24, 26 generates about 2.5 Amperes of current. The power output of the disclosed semiconductor device 10 is about 5.0125 Watts. Thus, as may be seen in the illustrative example, the disclosed semiconductor device 10 outputs 2.425 Watts more power than a conventional solar cell.

It is to be appreciated that the compensating current 142, 144, 146 for each sub-cell 20, 24, 26 may be determined based on either active control or passive control. If active control is employed, then the control modules 132, 134, 136 of the respective DC to DC power converter 122, 124, 126 may continually monitor the current generated by the respective sub-cells 22, 24, 26, and constantly update the respective compensating current 142, 144, 146 introduced back into the respective sub-cells 22, 24, 26 in order to balance the electrical current between each of the sub-cells 22, 24, 26 in substantially equal amounts. If passive control is employed, then the control modules 132, 134, 136 of the respective DC to DC power converter 122, 124, 126 may initially monitor the current generated by the respective sub-cells 22, 24, 26, and then permanently set the respective compensating current 142, 144, 146 introduced back into the respective sub-cells 22, 24, 26 in order to balance the electrical current between each of the sub-cells 22, 24, 26 in substantially equal amounts.

Although FIG. 2 illustrates a unique DC to DC converter is provided for each sub-cell 22, 24, 26, it is to be appreciated that in an alternative example, a single DC to DC converter may be used instead for each semiconductor device 10 (FIG. 1). However, although use of a single DC to DC converter is contemplated, it is to be appreciated that a separate control strategy would still be required to determine the individual compensating currents for each sub-cell 22, 24, 26.

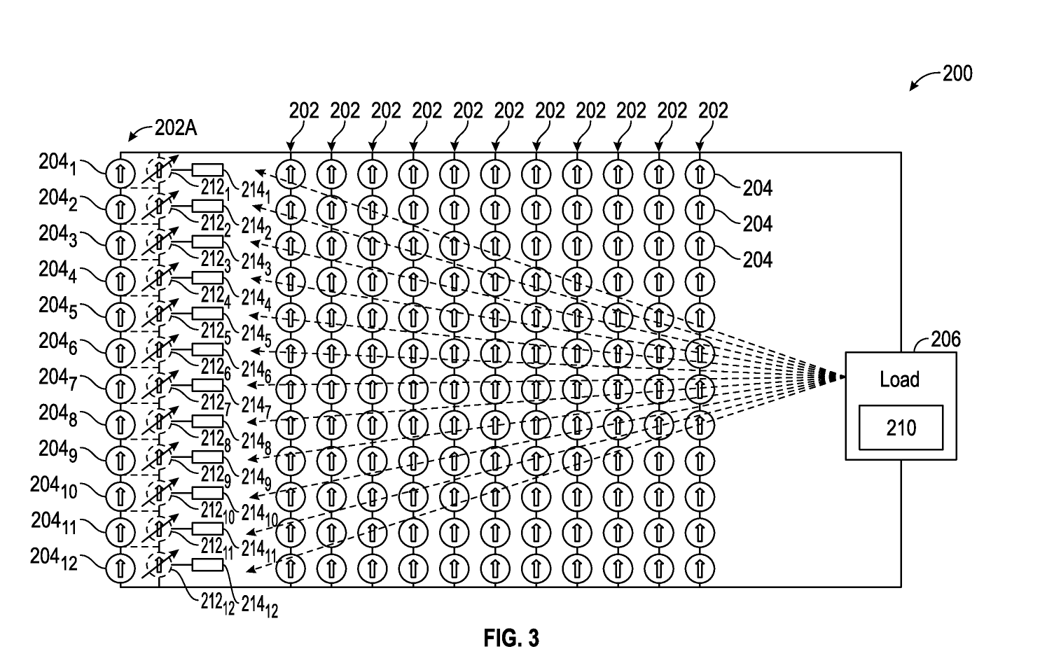

FIG. 3 is a schematic diagram of a solar panel 200. The solar panel 200 includes multiple strings 202 of solar cells 204 electrically coupled to one another in series. In one approach, each solar cell 204 may include the structure of the semiconductor device 10 shown in FIGS. 1-2 and described above. However, it is to be appreciated that in another example, some or all of the solar cells 204 may not employ the structure as described above, and are traditional or conventional solar cells known in the art. In one specific approach, the solar cells 204 may even be single junction solar cells. As seen in FIG. 3, an exemplary string 202A of solar cells 204₁-204₁₂ is illustrated, where each solar cell 204 may include a respective DC to DC converter 214₁-214₁₂. The DC to DC converters 214₁-214₁₂ each include circuitry for determining the total current generated by the respective solar cell 204. Furthermore, if the solar cells 204 include the structure as described above and shown in FIGS. 1-2, then the DC to DC converters 214₁-214₁₂ may each balance the current generated by the respective sub-cells 22, 24, 26 as described above such the respective electrical currents generated by each sub-cell 22, 24, 26 are substantially equal to one another. It should be appreciated that while FIG. 3 illustrates only the string 202A including respective DC to DC converters 214, this is merely done for purposes of simplicity and clarity in the drawing. Indeed, all of the solar cells 204 within the solar panel 200 include a respective DC to DC converter.

As seen in FIG. 3, each string 202 of solar cells 204 may be electrically coupled to a DC load 206 as well as to one another in parallel. It is to be appreciated that the DC load 206 may include a control module 210. The control module 210 may be in communication with each of the DC to DC converters 214 within the solar panel 200. The control module 210 includes control logic or circuitry for determining a respective compensating current 212₁-212₁₂ for each individual solar cell 204 within the solar panel 200 based on the total current generated by the individual solar cell 204. In other words, a separate control strategy is employed to determine a unique compensating current for each solar cell 204. The respective compensating currents 212₁-212₁₂ may be generated by the load 206, and are introduced back into the respective solar cell 204 through the respective DC to DC converter 214. The respective compensating currents 212₁-212₁₂ may balance the electrical current between each solar cell 204 within a respective string 202 of the solar panel 200 in substantially equal amounts. That is, each solar cell 204 within a respective string 202 of the solar panel 200 generates substantially equal current.

For example, in one illustrative example if solar cell 202₇ produces a maximum current of about 1.25 Amperes, and if solar cell 202₈ produces a minimum current of about 0.91 Amperes within a single string 202A, then a compensating current of about 0.34 Amperes will be introduced back into the solar cell 202₈ by the respective DC to DC converter 214₈. Furthermore, compensating current will be sent to the remaining solar cells 202₁-202₁₂ by the respective DC to DC converters 214₁-214₁₂ in order to balance the electrical current between each of the solar cells 204 such that each solar cell 202₁-202₁₂ generates a current of about 1.25 Amperes.

It is to be appreciated that determining the compensating current 212 for each solar cell 204 by the control module 210 may be determined using either active control or passive control. If active control is employed, then the control module 210 may continually monitor the current generated by each solar cells 204 within the solar panel 200, and constantly updates the respective compensating current 212 introduced back into the solar cells 204. If passive control is employed, then the control module 210 may initially monitor the current generated by each solar cells 204 within the solar panel 200, and then permanently sets the respective compensating current 212 introduced back into the respective solar cells 204.

FIG. 4 is an alternative example of a semiconductor device 300. The semiconductor device 300 includes a similar structure to the semiconductor device 10 shown in FIG. 1. Specifically, the semiconductor device 300 may include sub-cells 322, 324, 326 stacked on top of one another on a substrate 320, and respective tunnel junctions 354, 356 for electrically coupling the sub-cells 322, 324, 326 to one another. However, unlike the illustration of FIG. 1, the individual sub-cells 322 and 326 of the semiconductor device 300 include additional semiconductor layers. Specifically, the first sub-cell 322 includes a window layer 325, and the second sub-cell 326 includes a buffer layer 328. As explained below, electrical connections may be placed at the window layer 325 and the buffer layer 328. Although FIG. 4 illustrates a single buffer layer 328 located between the substrate 320 and the third sub-cell 326, those of ordinary skill in the art will readily appreciate that the semiconductor device 300 may include multiple buffer layers. Specifically, a buffer layer may be placed between any of the sub-cells 322, 324, 326, or between the substrate 320 and the sub-cell 326. Furthermore, it should also be appreciated that while only the first sub-cell 322 is illustrated including a window layer, in another approach a window layer may be grown on top of any or all of the individual sub-cells 322, 324, 326 as well.

The window layer 325 may be disposed along an upper surface 360 of a p-doped layer 330 of the first sub-cell 322. A seen in FIG. 4, the window layer 325 is positioned nearest to incident light L when compared to the remaining layers of the semiconductor device 300. The window layer 28 may be constructed of Group III-V materials such as, for example, GaInP. The buffer layer 328 may be positioned between an upper surface 372 of a p-doped layer 340 of the sub-cell 326 and a bottom surface 329 of the tunnel junction 354, and is electrically coupled to both the second sub-cell 324 and the third sub-cell 326. In the example as shown in FIG, 4, the buffer layer 328 may be epitaxially grown upon the upper surface 372 of the substrate 320. The buffer layer 328 may be, for example, a metamorphic transparent graded buffer, a metamorphic non-transparent graded buffer, nucleation layer, or a lattice-matched defect compensation layer. The buffer layer 328 may be used as a stress compensation layer when epitaxially growing the subsequent layers (i.e., the tunnel junctions 352, 354 and the sub-cells 322, 324) of the semiconductor device 300. Thus, the buffer layer 328 may substantially prevent defects when growing subsequent layers of the semiconductor device 300.

In the example as shown in FIG. 4, electrical contacts 402, 404 may be placed along an upper surface 410 of the window layer 325. The electrical contacts 402, 404 are electrically coupled to the first sub-cell 322, and connect the first sub-cell 322 to the DC to DC power converter 122 and the load 120 (FIG. 2). The second sub-cell 324 is stacked below the first sub-cell 322. However, a portion of the window layer 325 and the first sub-cell 322 have been removed using any known technique, which results in a first step 303. Furthermore, the removal of the window layer 325 and the first sub-cell 322 exposes a portion 301 of an upper surface 305 of the tunnel junction 352, while a remaining portion 309 of the upper surface 305 is covered by the first sub-cell 322. An electrical contact 408 may be placed along the exposed portion 301 of the upper surface 305 of the tunnel junction 352. The electrical contact 408 is electrically coupled to the second sub-cell 324 and connects the second sub-cell 324 to the DC to DC power converter 124 and the load 120 (FIG. 2).

The third sub-cell 326 is stacked below the second sub-cell 324, where a portion of the second sub-cell 324, a portion of the tunnel junction 352, and a portion of the tunnel junction 354 have all been removed using any known technique, which results in a second step 307. A portion 313 of an upper surface 312 of the buffer layer 328 is exposed, and a remaining portion 315 of the upper surface 312 of the buffer layer 328 is covered by the third sub-cell 326. An electrical contact 416 may be placed along the exposed portion 313 of the upper surface 312 of the buffer layer 328. The electrical contact 416 is electrically coupled to the third sub-cell 326, and connects the third sub-cell 326 to the DC to DC power converter 126 and the load 120 (FIG. 2). Finally, an electrical contact 418 may be placed along a bottom surface 319 of the substrate 320. The electrical contact 318 is electrically coupled to the substrate 320, and connects the substrate 320 to the load 120.

FIG. 5 is yet another example of a semiconductor device 600. The semiconductor device 600 includes a similar structure to the semiconductor device 10 shown in FIG. 1. Specifically, the semiconductor device 500 includes sub-cells 522, 524, 526 and respective tunnel junctions 552, 554, 556 for electrically coupling the sub-cells 522, 524, 526 to one another, or to a substrate 520. However, unlike the example as shown in FIG. 1, the individual sub-cells 522, 554, 556 of the semiconductor device 600 each include an LCL disposed along respective upper and lower surface of each sub-cell.

As seen in FIG. 5, the first sub-cell 522 includes an upper LCL 730 and a lower LCL 732. The second sub-cell 524 includes an upper LCL 734 and a lower LCL 736. The sub-cell 734 includes an upper LCL 738 and a lower LCL 740. The LCLs may be constructed of conductive materials such as, for example, graphene, a transparent oxide such as indium tin oxide (ITO), carbon nanotubes, or highly doped semiconductor material having a doping concentration of about 2×10²⁰/cm³. Those of ordinary skill in the art will appreciate that the LCLs may act as a buffer layer, a window layer, or a tunnel junction. In the example as shown in FIG. 5, the upper LCL 730 of the first sub-cell 522 is disposed along an upper surface 660 of a p-doped layer 630 of the first sub-cell 522. The lower LCL 732 is disposed between a bottom surface 662 of a n-doped layer 632 of the first sub-cell 522 and an upper surface 762 of the tunnel junction 552. The upper LCL 734 of the second sub-cell 524 may be disposed between a bottom surface 764 of the tunnel junction 552 and an upper surface 664 of a p-doped layer 636 of the second sub-cell 524. The lower LCL 736 of the second sub-cell 524 may be disposed between a bottom surface 666 of a n-doped layer 638 of the second sub-cell 524 and an upper surface 766 of the tunnel junction 554. The upper LCL 738 of the sub-cell 526 may be disposed between a bottom surface 768 of the tunnel junction 554 and an upper surface 668 of a p-doped layer 640 of the third sub-cell 526. The lower LCL 740 of the third sub-cell 526 may be disposed between a bottom surface 670 of a n-doped layer 642 of the third sub-cell 526 and an upper surface 766 of the tunnel junction 556

Continuing to refer to FIG. 5, two electrical contacts 702, 704 may be placed along an upper surface 700 of the LCL 730. The electrical contacts 702, 704 are electrically coupled to the first sub-cell 522, and connect the first sub-cell 522 to the power converter 122 (FIG. 2). The second sub-cell 524 is stacked below the first sub-cell 522. However, a portion of the first sub-cell 522 as well as the tunnel junction 552 have been removed using any known technique, which results in a first step 703. As seen in FIG. 5, a portion 710 of an upper surface 705 of the upper LCL 734 of the second sub-cell 524 is exposed, while a remaining portion 713 of the upper surface 705 of the upper LCL 734 of the second sub-cell 524 remains covered by the tunnel junction 552. An electrical contact 708 may be placed along the exposed portion 710 of the upper surface 705 of the upper LCL 734 of the second sub-cell 524. The electrical contact 708 is electrically coupled to the second sub-cell 724 and connects the second sub-cell 524 to the power converter 124 and the load 120 (FIG. 2).

The third sub-cell 726 is stacked below the second sub-cell 724, where a portion of the second sub-cell 724 as well as the tunnel junction 554 have both been removed using any known technique, which results in a second step 707. As seen in FIG. 5, a portion 715 of an upper surface 712 of the LCL 738 of the sub-cell 554 is exposed, while a remaining portion 717 of the upper surface 712 of the LCL 738 of the sub-cell 554 remains covered by the tunnel junction 554. An electrical contact 716 may be placed along the exposed upper surface 712 of the LCL 738. The electrical contact 716 is electrically coupled to the third sub-cell 726 and connects the third sub-cell 526 to the power converter 126 and the load 120 (FIG. 2). Finally, an electrical contact 718 may be placed along a bottom surface 719 of the substrate 520. The electrical contact 718 is electrically coupled to the substrate 520, and connects the substrate 520 to the load 120.

Referring generally to the figures, the disclosed approach for introducing compensating currents back into the individual sub-cells increases the respective operating efficiency and power produced by an individual multi junction solar cell. Indeed, as discussed above, in one illustrative example the disclosed multi junction solar cell may generate about twice the power that is generated by a conventional multi junction solar cell (the disclosed multi junction solar cell results in 5.0125 Watts, while a conventional solar cell results in only 2.5875 Watts of power). The disclosed multi junction solar cell may operate efficiently over a wide range of spectral illumination environments. The disclosed solar cells may also be tested for quantum efficiency using an electrical light biasing approach instead of a light biasing approach, which is currently used. Testing solar cells using the electrical light biasing approach may result in enhanced control and increased speed during quantum efficiency testing when compared to light biasing testing.

Furthermore, balancing the current generated by the respective multi junction solar cells within each string within a solar panel shown may eliminate the need to bin individual solar cells when constructing the solar panel. Binning typically involves measuring the output current capability of each solar cell in order to ensure that a string of solar cells within a solar panel each perform within a specified tolerance of one another. Moreover, sometimes a specific solar cell within a particular string is only able to produce a portion of the total current possible or is unable to produce any current at all based on factors such as aging, contamination, shadowing, light misalignment, light non-uniformity, or damage. The disclosed approach of balancing the current generated by each multi junction solar cell within a particular string of a solar cell may compensate for the various issues that may affect the performance of a single or multiple solar cells.

While the forms of apparatus and methods herein described constitute preferred examples of this invention, it is to be understood that the invention is not limited to these precise forms of apparatus and methods, and the changes may be made therein without departing from the scope of the invention.

What is claimed is:

1. A semiconductor device (10), comprising:
a first sub-cell (22) generating a first electrical current;
a second sub-cell (24) generating a second electrical current, wherein the first sub-cell (22) and the second sub-cell (24) are electrically coupled to one another in series; and
at least one power converter (122, 124, 126) electrically coupled to both the first sub-cell (22) and the second sub-cell (24), the at least one power converter (122, 124, 126) introducing a compensating current (142, 144, 146) into at least one of the first sub-cell (22) and the second sub-cell (24) to balance the first electrical current and the second electrical current to be substantially equal to one another.

2. The semiconductor device (10) of claim 1, comprising at least one first electrical contact (102, 104) electrically coupling the first sub-cell (22) to the at least one power converter (122, 124, 126).

3. The semiconductor device (10) of claim 2, comprising a contact layer (50) disposed along an upper surface (60) of the first sub-cell 22, wherein the at least one first electrical contact (102, 104) is electrically coupled to the contact layer (50).

4. The semiconductor device (10) of claim 2, comprising a tunnel junction (52) located between the first sub-cell (22) and the second sub-cell (24), wherein a portion (106) of an upper surface (105) of the tunnel junction (52) is covered by the first sub-cell (22) and a remaining portion (101) of the upper surface (105) of the tunnel junction (52) is exposed.

5. The semiconductor device (10) of claim 4, comprising a second electrical contact (108) disposed along the remaining portion (101) of the upper surface (105) of the tunnel junction (52) that is exposed, wherein the second electrical contact (108) electrically couples the second sub-cell (24) to the at least one power converter (122, 124, 126).

6. The semiconductor device (10) of claim 2, wherein the first sub-cell (322) includes a window layer (325), and wherein the at least one first electrical contact (402, 404) is electrically coupled to the window layer (325).

7. The semiconductor device (10) of claim 2, wherein the first sub-cell (22) includes a lateral conduction layer (LCL) (730), and wherein the at least one first electrical contact (702, 704) is electrically coupled to LCL (730).

8. The semiconductor device (10) of claim 1, wherein the at least one power converter (122, 124, 126) is a direct current (DC) to DC buck power converter.

9. The semiconductor device (10) of claim 1, wherein the at least one power converter (122, 124, 126) determines the compensating current (142, 144, 146) based on one of active control and passive control.

10. The semiconductor device (10) of claim 1, wherein the first sub-cell (522) includes a first upper lateral conduction layer (LCL) (730) and a second lower LCL (732), and the second sub-cell (524) includes a second upper LCL (734) and a second lower LCL (736).

11. The semiconductor device (10) of claim 10, comprising electrical contacts (702, 704, 708) electrically coupled to the first upper LCL (730) and the second upper LCL (734), wherein the electrical contacts (702, 704, 708) electrically couple the first sub-cell (522) and the second sub-cell (524) to the at least one power converter (122, 124, 126).

12. The semiconductor device (10) of claim 1, comprising a plurality of electrical contacts (102, 104, 108) for electrically coupling the first sub-cell (22) and the second sub-cell (24) to the at least one power converter (122, 124, 126).

13. The semiconductor device (10) of claim 1, comprising at least one buffer layer (328) electrically coupled to the first sub-cell (324) and the second sub-cell (326).

14. The semiconductor device (10) of claim 13, comprising an electrical contact (416) electrically coupled to the at least one buffer layer (328), wherein the electrical contact (416) electrically couples one of the first sub-cell (324) and the second sub-cell (326) to the at least one power converter (122, 124, 126).

15. A solar panel (200), comprising:
at least one solar cell string (202) including a plurality of solar cells (204) electrically coupled to one another in series, each solar cell (204) of the plurality of solar cells (204) generating a respective electrical current; and
a load (206) including a control module (210), the load (206) electrically coupled to the at least one solar cell string (202), wherein the control module (210) determines a compensating current (212) for each individual solar cell (204) of the plurality of solar cells (204), the compensating current (212) balancing the respective electrical current generated by each of the plurality of solar cells (204) within the at least one solar cell string (202) in substantially equal amounts.

16. The solar panel (200) of claim 15, comprising respective power converters (214) for each solar cell (204) of the plurality of solar cells, wherein the respective power converters (214) determine the respective electrical current generated by a respective solar cell (204).

17. The solar panel (200) of claim 16, wherein each solar cell (204) of the plurality of solar cells (204) comprises a first sub-cell (22) generating a first electrical current and a second sub-cell (24) generating a second electrical current, wherein each of the respective power converters (214) is electrically coupled to both the first sub-cell (22) and the second sub-cell (24) of the respective solar cell (204).

18. The solar panel (200) of claim 17, wherein each of the respective power converters (214) introduce a second compensating current (142, 144, 146) into at least one of the first sub-cell (22) and the second sub-cell (24) of the respective solar cells (204) to balance the first electrical current and the second electrical current to be substantially equal to one another.

19. A method of balancing current within a multi junction solar cell (10), the method comprising:
generating a first electrical current by a first sub-cell (22);
generating a second electrical current by a second sub-cell (24), wherein the first sub-cell (22) and the second sub-cell (24) are electrically coupled to one another in series;
electrically coupling both the first sub-cell (22) and the second sub-cell (24) to at least one power converter (122, 124, 126); and
introducing a compensating current (142, 144, 146) by the at least one power converter (122, 124, 126) into at least one of the first sub-cell (22) and the second sub-cell (24) to balance the first electrical current and the second electrical current to be substantially equal to one another.

20. The method of claim 19, comprising electrically coupling the first sub-cell (22) to the at least one power converter (122, 124, 126) by at least one electrical contact (102, 104).
